(19) United States
(12) Patent Application Publication
(10) Pub. No.: US 2024/0300425 A1
(43) Pub. Date: Sep. 12, 2024

(54) POWER CONTROL MODULE ASSEMBLY

(71) Applicant: BorgWarner Inc., Auburn Hills, MI (US)

(72) Inventors: Lorenzo Caprotti, Vimercate (IT); Philippe Alain Clayton, Camparada (IT)

(21) Appl. No.: 18/117,649

(22) Filed: Mar. 6, 2023

(51) Int. Cl. B60R 16/023; B60R 16/033; H02G 3/08; H02G 15/013

(52) U.S. Cl. CPC B60R 16/0238; B60R 16/033; H02G 3/083; H02G 15/013

(57) ABSTRACT

A sealing adapter bushing assembly for a power control module (PCM) in an electric vehicle (EV) includes an adapter bushing base, configured to be received within an opening in a housing of the PCM; a terminal seal engaged with a surface of the adapter bushing base and is configured to engage a surface of a terminal of the PCM; and a housing seal engaged with a surface of the adapter bushing base and is configured to engage a surface of the housing.

### TECHNICAL FIELD

The present application relates to electric vehicles (EVs) and, more particularly, to power control modules used with EVs.

### BACKGROUND

Vehicles are increasingly propelled by electric motors rather than ICEs. The supporting infrastructure used to control and otherwise operate the electric vehicles (EVs) is different than what has traditionally been used in vehicles propelled by ICEs. Rather from fuel tanks and fuel ignition, EVs commonly use electric motors, batteries, and power control modules that regulate electric current supplied to the electric motor. Power control modules can be electrically connected to both the electric motor and the vehicle batteries such that the modules invert DC current from the battery to rotate an output shaft of the electric motor. The supply of the electric voltage and current to power control modules can be significant. And EVs are configured to operate in a wide variety of environments. So it's helpful to prevent the ingress of elements into a power control module.

### SUMMARY

In one implementation, a sealing adapter bushing assembly for a power control module (PCM) in an electric vehicle (EV) includes an adapter bushing base, configured to be received within an opening in a housing of the PCM; a terminal seal engaged with a surface of the adapter bushing base and is configured to engage a surface of a terminal of the PCM; and a housing seal engaged with a surface of the adapter bushing base and is configured to engage a surface of the housing.

In another implementation, a sealing adapter bushing assembly for a PCM in an EV includes an adapter bushin base, configured to be received within an opening in a housing of the PCM, having an annular shoulder with a surface confronting an inner surface of the housing and a housing groove shaped to engage the inner surface of the housing and an outer surface of the housing; a terminal seal engaged with a surface of the adapter bushing base and is configured to engage a surface of a terminal of the PCM; and a housing seal engaged with the surface of the annular shoulder and the inner surface of the housing.

In yet another implementation, a sealing adapter bushing assembly for a PCM in an EV includes an adapter bushing base, configured to be received within an opening in a housing of the PCM, having an annular shoulder with a surface confronting an inner surface of the housing and a housing groove shaped to engage the inner surface of the housing and an outer surface of the housing; a terminal seal engaged with a surface of the adapter bushing base and is configured to engage a surface of a terminal of the PCM; and a housing seal engaged with the surface of the annular shoulder and the inner surface of the housing.

### BRIEF DESCRIPTION OF THE DRAWINGS

FIG. 1 is a perspective view depicting an implementation of a

power control module (PCM) used in an electric vehicle (EV);

FIG. 2 is a cross-sectional view depicting an implementation of a PCM used in an EV;

FIG. 3 is another cross-sectional view depicting an implementation of a PCM used in an EV;

FIG. 4 is a cross-sectional view depicting an implementation of a sealing adapter bushing assembly used in a PCM;

FIG. 5 is a cross-sectional view depicting another implementation of a sealing adapter bushing assembly used in a PCM;

FIG. 6 is a perspective view depicting another implementation of a sealing adapter bushing assembly used in a PCM;

FIG. 7 is a cross-sectional view depicting yet another implementation of a sealing adapter bushing assembly used in a PCM; and

FIG. 8 is a perspective view depicting yet another implementation of a sealing adapter bushing assembly used in a PCM.

### DETAILED DESCRIPTION

A power control module in an electric vehicle (EV) includes a housing that encapsulates electrical components. The housing has openings permitting electrical terminals to pass through and electrically connect the electrical components to other portions of the EV, such as an EV battery and/or an electric motor. Multiple weather resistant seals are placed adjacent the openings. Each terminal can be received through the housing by a sealing adapter bushing assembly that communicates with the opening. One seal can engage an outer surface of the terminal and an inner surface of the sealing adapter bushing assembly. Another seal can engage a surface of the housing and an outer surface of the adapter bushing assembly. The use of more than one seal between the housing and the terminal can help compensate for both vertical and horizontal misalignments between the housing and the terminal without sacrificing weather resistance. The sealing adapter bushing assembly described here can meet very particular liquid ingress prevention standards. For instance, the sealing adapter bushing assembly described can have an Ingress Protection (IP) code rating of at least 67, meaning that the assembly is dust-tight as well as water-tight up to a meter in depth for at least 30 minutes.

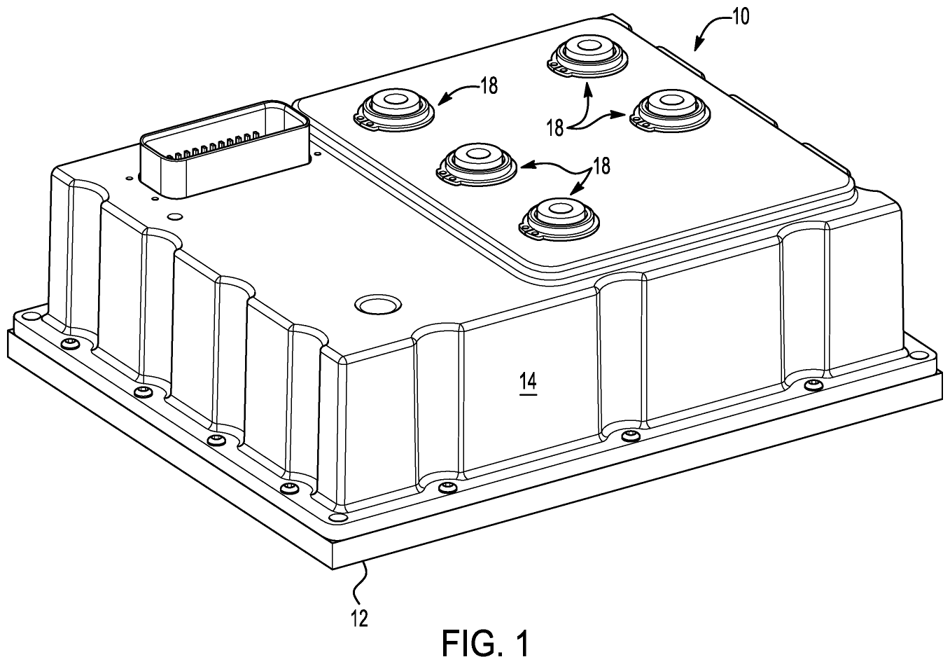

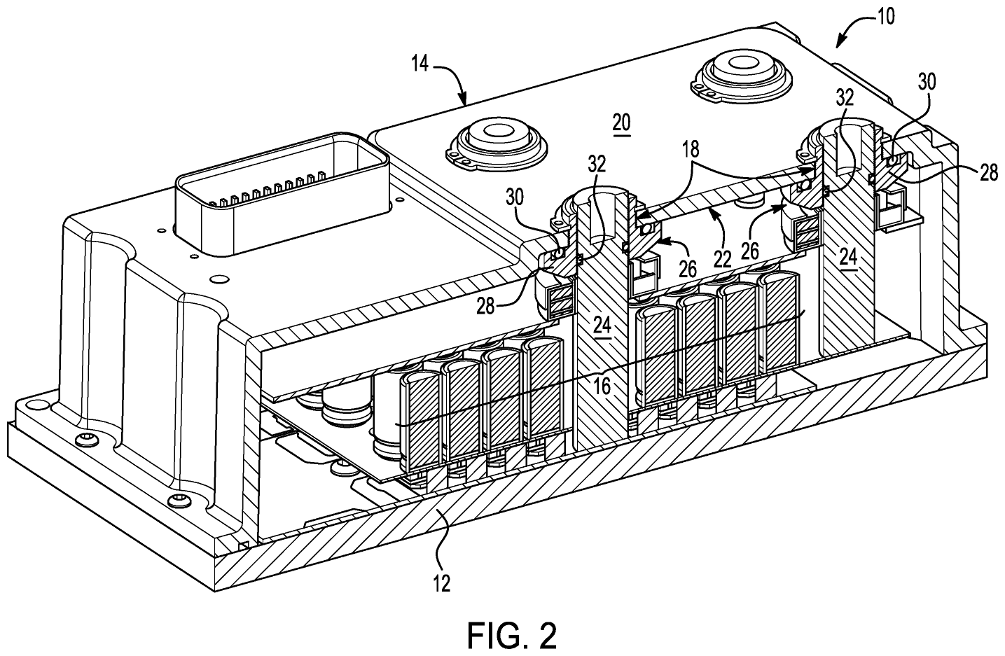

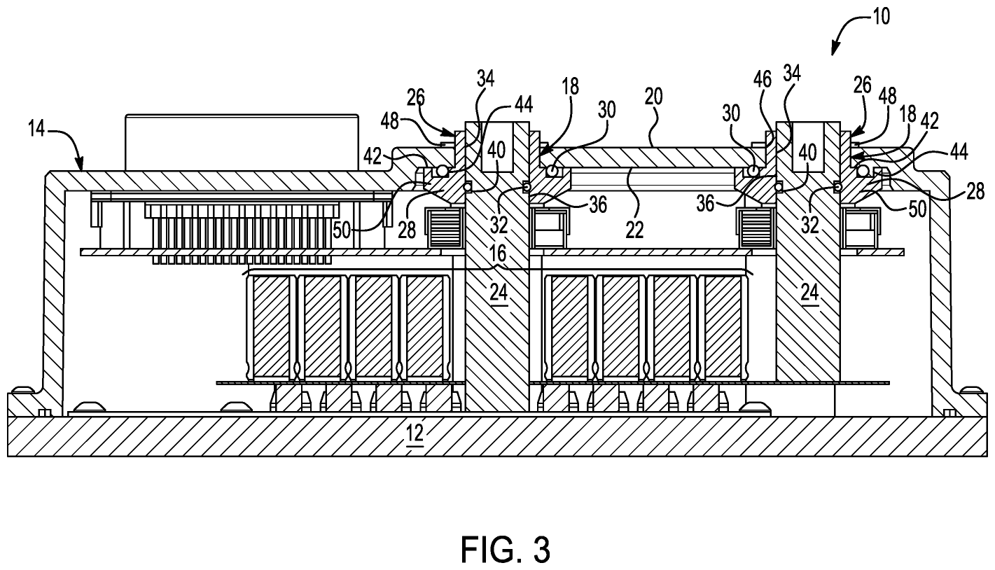

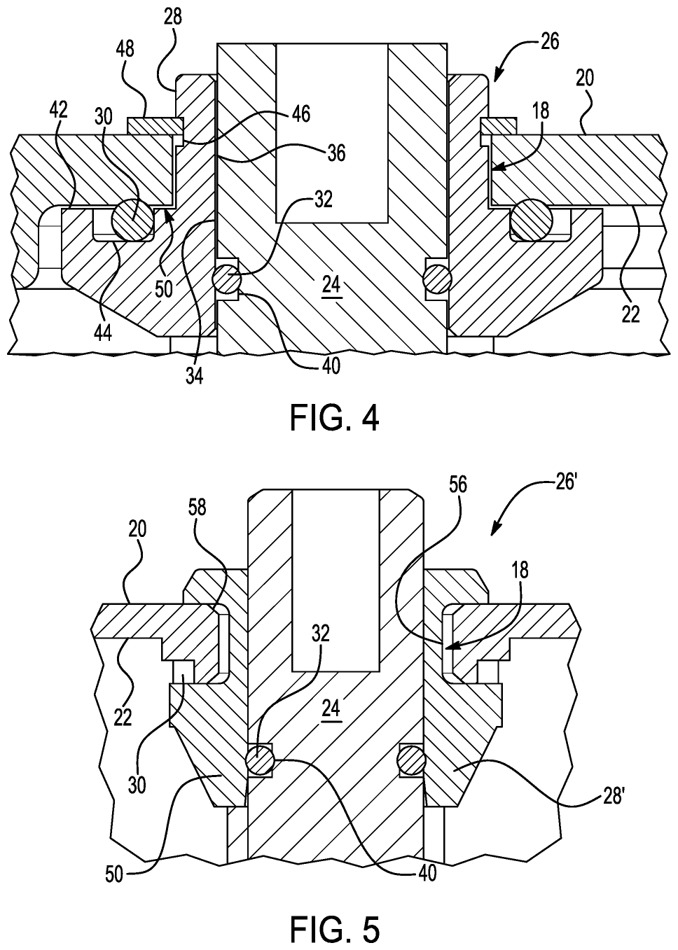

An implementation of a power control module (PCM) 10 used with an EV is shown in FIGS. 1-4. The power control module 10 includes a base 12 and a housing 14 that join together to form a weather resistant enclosed space for receiving and protecting electrical components 16 used to implement power control for the EV. The base 12 can be relatively planar and is rigidly attached to the PCM 10 to the EV by fasteners or other attachments. The base 12 and housing 14 can be formed from plastic or metal, depending on the application. The housing 14 be shaped so that, when joined with the base 12, a cavity exists within which electrical components 16 that control EV propulsion are contained. The housing 14 can include a plurality of openings 18 that extend from an outer surface 20 to an inner surface 22 of the housing 14. The electrical components 16 can be combined to implement a wide array of power electronics functionality. For example, the power electronics can invert DC current supplied by the EV battery into AC current that can induce angular movement of a rotor/shaft of the EV motor relative to the stator. The electrical components 16 can include switches, such as MOSFETs, a transformer, diodes, inductors, resistors, and/or microprocessors carried by one or more printed circuit boards forming the circuit trace electrically linking the electrical components. The term power control module should be viewed as broadly including any housing that encapsulates electrical components on an electric vehicle. The term electric vehicle or “EV” can refer to vehicles that are propelled, either wholly or partially, by electric motors. EV can refer to electric vehicles, plug-in electric vehicles, hybrid electric vehicles, and battery-powered vehicles, to name a few.

A plurality of terminals 24 can extend from the cavity within the housing 14 through the openings 18 so that the terminals 24 are exposed outside of the housing 14. The terminals 24 electrically connect to electrical components 16 and/or a PCB within the cavity. The terminal 24 can extend from the base 12 of the PCM 10 in a Z-direction through the opening 18 and slightly beyond the outer surface 20 of the housing 14. While some terminals 24 may engage the base, others may extend in a Z-direction from a surface of a PCB in the cavity through the opening 18 and slightly beyond the outer surface 20 of the housing 14.

A sealing adapter bushing assembly 26 can engage the terminal 24 and the housing 14 to secure the terminal 24 to the housing 14 in a weather resistant way. The sealing adapter bushing assembly 26 can include an adapter bushing base 28, a housing seal 30, and a terminal seal 32. The adapter bushing base 28 can include an inner diameter 34 in close conformity to an outer surface 36 of the terminal 24.

The inner diameter 34 can be shaped so that the adapter bushing base 28 concentrically receives the terminal 24. The surface of the inner diameter 34 of the adapter bushing base 28 can engage the terminal seal 32 positioned between the inner diameter 34 and the outer surface 36 of the terminal 24. The outer surface 36 of the terminal 24 can include an annular groove 40 shaped to receive the terminal seal 32 to prevent movement of the seal 32 axially along the terminal 24 yet the radial depth of the groove 40 can be selected such that the terminal seal 32 extends in a radial direction relative to a center of the terminal 24 beyond the outer surface 36 of the terminal 24. The inner diameter 34 of the adapter bushing base 28 can be selected so that when the terminal 24 is received within the inner diameter 34 of the adapter bushing base 28, the terminal seal 32 can be slightly compressed thereby creating a weather-resistant seal. The inner diameter 34 of the adapter bushing base 28, the cross-section size of the terminal seal 32, and the outer diameter of the terminal 24 can be selected to permit movement of the terminal 24 relative to the opening in the x-direction and the y-direction while still maintaining a weather-resistant engagement of the terminal seal 32 between the outer diameter of the terminal 24 and the inner diameter 34 of the adapter bushing base 28.

An outer surface 42 of the adapter bushing base 24 can include a housing seal groove 44 for receiving the housing seal 30 and a retaining groove 46 for receiving a retaining clip 48 that can secure the sealing adapter bushing assembly 26 to the housing 14 and apply a desired amount of compressive force to the housing seal 30 between an outer surface 42 of the adaptor bushing base 28 and the inner surface 22 of the housing 14. The amount of compression applied to the seal 30 can vary based on a variety of factors, such as variations in alignment of electrical components, yet a weather-tight seal can be maintained.

The adaptor bushing base 28 can include an annular shoulder 50 that extends radially-outwardly away from the terminal 24. The shoulder 50 can include housing groove 44 that faces toward the inner surface 22 of the housing 14. The housing seal 30 can be received within the housing seal groove 44 and, when the retaining clip 48 biases the adapter bushing base 28 in an axial direction relative to the length of the terminal 24, the housing seal 30 can be compressed between the housing seal groove 44 and the inner surface of the housing 22. The housing seal 30 cross-sectional shape and diameter can be chosen such that the seal 30 sits at least partially outside of the housing seal groove 44 so that the amount of compression applied to the seal 30 can vary due to factors, such as variations in alignment of electrical components yet a weather-tight seal can be maintained. The retaining clip 48 can be received within the retaining groove 46 and engage an outer surface 20 of the housing 14 to hold the terminal 24 in place and adequately compress the housing seal 30.

The seals 30, 32 can be formed from any one of a variety of different materials, such as electrometric material.

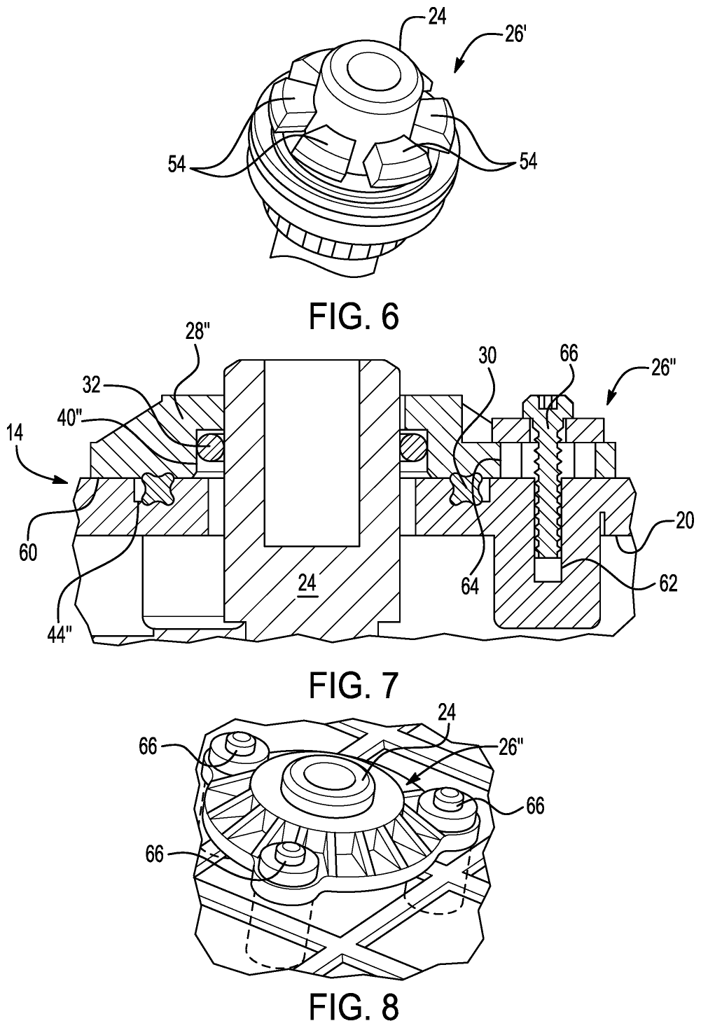

Turning to FIGS. 5-6, another implementation of a sealing adapter bushing assembly 26′ is shown. The sealing adapter bushing assembly 26′ includes an adapter bushing base 28′ having an integrated retaining clip.

That is, rather than a retaining groove that receives a retaining clip, the adapter bushing base 28′ can include a plurality of opposably biased tabs 54 having a housing groove 56 that engages the inner surface 22 and the outer surface 20 of the housing 14 and the annular shoulder 50 that engages the housing seal 30 with the inner surface 22 of the housing 14. The axial length of the housing groove 56 can be specified based on the thickness of the housing 14, size of the housing seal 30, and/or desired amount of allowable movement in the z-direction. As the adapter bushing base 28′ is inserted into the opening 18, the tabs 54 can be biased radially inwardly toward a center of the opening 18 as the adapter bushing base 28′ is inserted into the opening 18. Once the housing seal 30 is sufficiently compressed an opposing shoulder 58 at a distal end of the tabs 54 can engage the outer surface 20 of the housing 14 thereby holding the adapter bushing base 28′ in place within the opening 18.

Another implementation of the sealing adapter bushing assembly 26″ is shown in FIGS. 7-8. The adapter bushing assembly 26″ can include one or more mechanical fasteners that secure the adapter bushing base 28″ to the housing 14. In this implementation, the adapter bushing base 28″ can include an inner surface 60 and the housing seal 30 can be received within the groove 44″ in between the adapter bushing base 28″ and the outer surface 20 of the housing 14. The housing 14 can include receptacles 62 corresponding to apertures 64 in the adapter bushing base 28″. A threaded connector 66, such a bolt, can pass through the aperture 64 and engage the receptacle 62 to draw the adapter bushing base 28″ onto the outer surface 20 of the housing 14 thereby compressing the housing seal 30. In this implementation, the terminal 14 can also include a terminal seal 32 received within the annular groove 40 as described above.

It is to be understood that the foregoing is a description of one or more embodiments of the invention. The invention is not limited to the particular embodiment(s) disclosed herein, but rather is defined solely by the claims below. Furthermore, the statements contained in the foregoing description relate to particular embodiments and are not to be construed as limitations on the scope of the invention or on the definition of terms used in the claims, except where a term or phrase is expressly defined above. Various other embodiments and various changes and modifications to the disclosed embodiment(s) will become apparent to those skilled in the art. All such other embodiments, changes, and modifications are intended to come within the scope of the appended claims.

As used in this specification and claims, the terms “e.g.,” “for example,” “for instance,” “such as,” and “like,” and the verbs “comprising,” “having,” “including,” and their other verb forms, when used in conjunction with a listing of one or more components or other items, are each to be construed as open-ended, meaning that the listing is not to be considered as excluding other, additional components or items. Other terms are to be construed using their broadest reasonable meaning unless they are used in a context that requires a different interpretation.

What is claimed is:

1. A sealing adapter bushing assembly for a power control module (PCM) in an electric vehicle (EV), comprising:
an adapter bushing base, configured to be received within an opening in a housing of the PCM;
a terminal seal engaged with a surface of the adapter bushing base and is configured to engage a surface of a terminal of the PCM; and
a housing seal engaged with a surface of the adapter bushing base and is configured to engage a surface of the housing.

2. The sealing adapter bushing assembly recited in claim 1, further comprising a terminal including a terminal groove shaped to receive the terminal seal.

3. The sealing adapter bushing assembly recited in claim 1, wherein the adapter bushing base includes a housing seal groove shaped to receive the housing seal.

4. The sealing adapter bushing assembly recited in claim 1, wherein the adapter bushing base includes an annular shoulder, with a surface, including the housing seal groove, facing an inner surface of the housing.

5. The sealing adapter bushing assembly recited in claim 1, wherein the adapter bushing base includes a housing groove that engages an inner surface of the housing and an outer surface of the housing.

6. The sealing adapter bushing assembly recited in claim 1, wherein the adapter bushing base includes a plurality of opposably biased tabs that engage the housing.

7. The sealing adapter bushing assembly recited in claim 1, further comprising a plurality of receptacles coupled to the housing configured to receive threaded connectors and draw the adapter bushing base closer to the housing.

8. The sealing adapter bushing assembly recited in claim 1, wherein the adapter bushing base includes a retaining groove configured to receive a retaining clip that axially biases the sealing adapter bushing assembly to compress the housing seal.

9. A sealing adapter bushing assembly for a power control module (PCM) in an electric vehicle (EV), comprising:
an adapter bushing base, configured to be received within an opening in a housing of the PCM, having an annular shoulder with a surface confronting an inner surface of the housing and a housing groove shaped to engage the inner surface of the housing and an outer surface of the housing;
a terminal seal engaged with a surface of the adapter bushing base and is configured to engage a surface of a terminal of the PCM; and
a housing seal engaged with the surface of the annular shoulder and the inner surface of the housing.

10. The sealing adapter bushing assembly recited in claim 9, further comprising a terminal including a terminal groove shaped to receive the terminal seal.

11. The sealing adapter bushing assembly recited in claim 9, wherein the adapter bushing base includes a plurality of opposably biased tabs that engage the housing.

12. A sealing adapter bushing assembly for a power control module (PCM) in an electric vehicle (EV), comprising:
an adapter bushing base, configured to be received at an outer surface of a housing of the PCM, having one or more apertures;
a housing seal engaging an outer surface of the housing and the adapter bushing base;
a terminal seal positioned between the adapter bushing base and the terminal; and
threaded connectors that pass through the apertures to engage receptacles in the housing and compress the housing seal between the adapter bushing base and the housing.

13. The sealing adapter bushing assembly recited in claim 12, wherein the terminal seal is positioned axially outside of an outer surface of the housing.

14. The sealing adapter bushing assembly recited in claim 12, further comprising a groove formed in an outer surface of the housing that receives the housing seal.
